(19) United States
(12) Patent Application Publication
(10) Pub. No.: US 2005/0107262 A1
(43) Pub. Date: May 19, 2005

(54) Information recording method using superconduction having bands, calculating method, information transmitting method, energy storing method, magnetic flux measuring method, and quantum bit construction method

(75) Inventors: Yasumoto Tanaka, Ibaraki (JP); Akira Iyo, Tsukuba-shi (JP); Kazuyasu Tokiwa, Tsukuba-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Nat. Inst. of Advanced Industrial Sci. and Tech, Tokyo (JP)

(21) Appl. No.: 10/494,325

(22) PCT Filed: Oct. 10, 2002
(86) PCT No.: PCT/JP02/10533

(30) Foreign Application Priority Data
Nov. 1, 2001 (JP) 2001-337020

(51) Int. Cl. H01L 39/24

(52) U.S. Cl. 505/474

(57) ABSTRACT

A recording method that records information in soliton units, a computing method that performs a computation, an information transmission method, an energy storage method, a magnetic flux measurement method and a quantum bit constitution method utilize the properties of phase solitons manifested between superconducting order parameters present in multiple bands in a superconductor having a multiple bands. The phase difference soliton is maintained, so information can be stored in the form of phase differences. Moreover, −Θsoliton phase slip will also be present when the same energy is carried in the reverse direction, so the soliton itself can have a + or − sign. The soliton enables storage of energy not accompanied by magnetic flux. Also, with soliton units, magnetic flux can be measured with greater precision by discriminating external magnetic flux. Moreover, using solitons and anti-solitons makes it possible to constitute quantum bits required in quantum measurements.

### TECHNICAL FIELD

In a superconductor having multiple bands, this invention relates to an information recording method, a computing method, an information transmission method, an energy storage method, a magnetic flux measurement method and a quantum bit constitution method utilizing phases between superconducting order parameters present in the multiple bands.

### BACKGROUND ART

In conventional superconduction, superconducting electronics utilizing superconduction phase differences have utilized only phase differences at spatially different arrangements. Also, with respect to the storing of energy, energy is stored using the flow of electric current, accompanying the induction of a magnetic field in the superconductor.

Josephson devices are typical of superconducting devices that utilize this type of technology. That is, they are superconductor devices that utilize a method utilizing the phase difference between two different superconductors disposed in a spatially adjoining fashion (hereinafter, a superconductor device utilizing this method is referred to as a AJosephson device based on spatial arrangement@). It is necessary to control the boundary properties of a Josephson device based on spatial arrangement. The difficulty of controlling the boundaries of a Josephson junction, particularly a Josephson device in a high temperature superconductor, is a major obstacle to practical application.

In the field of superconductor-based energy storage, there are a method in which a persistent current is set up in a superconducting magnet and electromagnetic energy stored therein, and a method in which a superconductor is levitated in a magnetic field and energy is stored using kinetic energy from the rotation of the superconductor. These methods are accompanied by the constant generation of magnetic flux, so where energy loss cannot be ignored, such as energy loss from magnetic flux creep in a high temperature superconductor, the operating temperature becomes a temperature that is quite lower than the superconducting transition temperature.

The object of the present invention is to provide an information recording method, a computing method, an information transmission method, a magnetic flux measurement method, a quantum bit constitution method and an energy storage method in which a magnetic field produced by a persistent current is not generated, utilizing a principle of a new Josephson device that does not require control of boundaries in a superconductor.

### DISCLOSURE OF THE INVENTION

The information recording method of the present invention utilizes a superconductor having multiple bands and comprises the step of recording information, utilizing phase differences between superconducting order parameters present in the multiple bands in the superconductor.

The computing method of the present invention utilizes a superconductor having multiple bands and comprises the step of performing a computation, utilizing phase difference solitons between superconducting order parameters present in multiple bands in the superconductor.

The information transmission method of the present invention utilizes a superconductor having multiple bands and comprises the step of transmitting information in units of phase difference solitons between superconducting order parameters present in the multiple bands in the superconductor.

The energy storage method of the present invention utilizes a superconductor having multiple bands and is based on phase difference solitons between superconducting order parameters present in the multiple bands in the superconductor.

The magnetic flux measurement method of the present invention utilizes a superconductor having multiple bands and comprises the step of measuring magnetic fluxoid quantum in unit phase difference solitons between superconducting order parameters present in the multiple bands in the superconductor.

The quantum bit constitution method of the present invention utilizes a superconductor having multiple bands to constitute quantum bits and comprises the step of utilizing phase differences between superconducting order parameters present in the multiple bands in the superconductor.

As described in the above, the present invention utilizes the properties of phase difference solitons arising between superconducting order parameters present in multiple bands in a superconductor without requiring boundary control of Josephson junctions, thereby facilitating practical application and also making it possible to keep down energy loss.

### BRIEF DESCRIPTION OF DRAWINGS

FIG. 1 is an explanatory view showing order parameters of a superconductor having multiple bands according to the present invention.

FIG. 2 is an explanatory view showing solitons created in a superconductor having multiple bands.

FIG. 3 shows rotation of phase difference between the order parameters produced in a superconductor having multiple bands.

FIG. 4 is an explanatory view showing the recording method of the present invention.

FIG. 5 is an explanatory view showing the computing method of the present invention.

FIG. 6 is an explanatory view showing the information transmission method of the present invention.

FIG. 7 is an explanatory view showing the energy storage method of the present invention.

FIG. 8 is an explanatory view showing the magnetic flux measurement method of the present invention.

FIG. 9 is an explanatory view showing the quantum bit constitution method of the present invention.

### BEST MODE FOR CARRYING OUT THE INVENTION

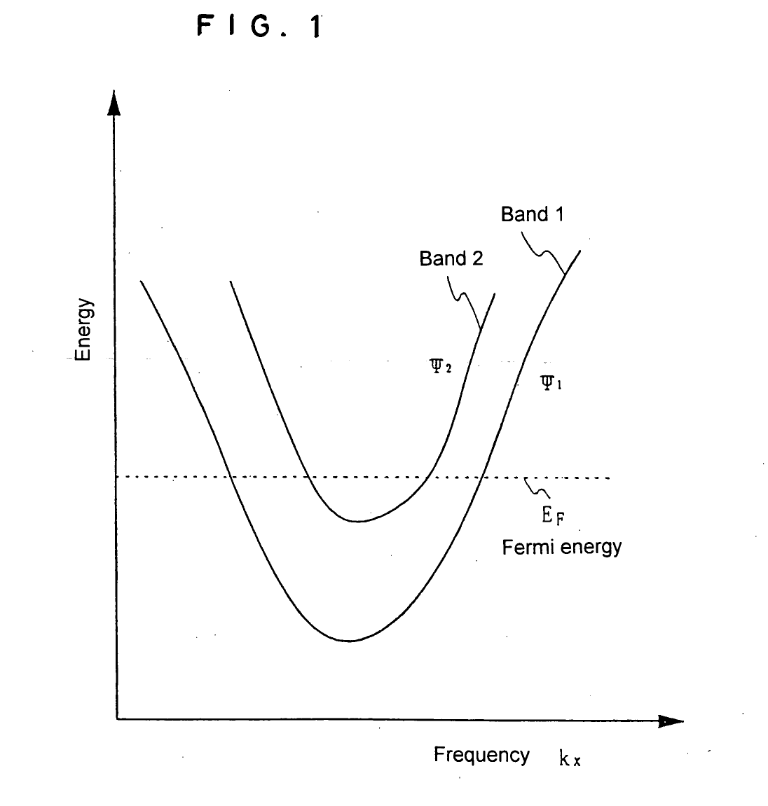

The present invention utilizes phase between superconductor electrons present in the bands of a superconductor having multiple bands. Superconductors having multiple bands include CuₓBa₂Ca₃CuO_{y}. FIG. 1 is a one-dimensional conceptual representation of the relationship between the electron energy and the wave number of a superconductor having two bands. An explanation will now be given with respect to a one-dimensional model in which there are two weakly interacting order parameters ψ1 and ψ2, each on a different band. By analogy, it is clear that the same kind of effect will be presented in the case of a strong interaction or when the plurality of bands numbers three or more.

Mathematically, the interaction between order parameters is the same as a Josephson type interaction. If the order parameters are expressed as an electron pair wave function using a Ginzburg model, the superconductor order parameter in band ν will be as in equation (1).

Here, N_{ν} and θ_{ν} are the density of the superconductor electrons and the order parameter phase on the band ν.
ψ_{ν}=\sqrt{N_{ν}}exp(iθ_{ν}) (1)

Based on a one-dimensional Ginzburg model, it is known that the Gibbs energy density of the superconductor electrons in the two bands can be described by the following equation (2). Equations (3) to (5) show an approximation of equation (2). Here, α_{ν}, β_{ν} and γ are parameters (γ is a parameter representing interband superconductor electron interaction), and m_{ν} is the mass of the band ν superconductor electrons.

$$\begin{matrix}\begin{matrix}g ( x ) = {\sum }_{v = 1 , 2} {α}_{v} {\vert {ψ}_{v} ( x ) \vert}^{2} + {\sum }_{v = 1 , 2} \frac{{β}_{v}}{2} {\vert {ψ}_{v} ( x ) \vert}^{4} + \\ {\sum }_{v} \frac{{\overline{h}}^{2}}{2 {m}_{μ}} {\vert \frac{\partial {ψ}_{v}}{\partial x} \vert}^{2} + γ ( {ψ}_{1}^{*} {ψ}_{2} + {ψ}_{2}^{*} {ψ}_{1} )\end{matrix} & ( 2 ) \\ {g}_{θ} ( x ) = {\sum }_{v = 1 , 2} \frac{{\overline{h}}^{2} {N}_{v}}{2 {m}_{v}} {\vert {∇}_{x} {θ}_{v} \vert}^{2} + 2 γ \sqrt{{N}_{1} {N}_{2}} cos ( {θ}_{1} - {θ}_{2} ) & ( 3 ) \\ {g}^{N} s ( x ) = {\sum }_{v , 1 , 2} {α}_{v} {N}_{v} + {\sum }_{v = 1 , 2} \frac{{β}_{v}}{2} {N}_{v}^{2} & ( 4 ) \\ g ( x ) = {g}_{θ} ( x ) + {g}^{N} s ( x ) & ( 5 )\end{matrix}$$

When no supercurrent flows in the superconductor (Je=ΣehN_{ν}/m_{ν}, Lₓθ_{ν}=0), the relationships of equations (6) to (9) obtain.

$$\begin{matrix}When γ < 0 \\ {θ}_{2} = - \frac{{N}_{1} {m}_{2}}{{N}_{2} {m}_{1}} {θ}_{1} & ( 6 ) \\ φ = {θ}_{1} - {θ}_{2} & ( 7 ) \\ When γ > 0 \\ {θ}_{2} = π - \frac{{N}_{1} {m}_{2}}{{N}_{2} {m}_{1}} {θ}_{1} & ( 8 ) \\ φ = {θ}_{1} - {θ}_{2} + π & ( 9 )\end{matrix}$$

In the free energy represented by equation (2), there is a state in which the energy becomes minimum that is a stable state. By using variation δ_{g}=0 in equation (2), the following equation (10) is obtained.

$$\frac{{\partial }^{2} φ}{\partial {x}^{2}} = \frac{1}{{L}^{2}} sin φ = 0 \\ However , \\ \frac{1}{{m}_{0}} = \frac{{N}_{1} {N}_{2}}{{m}_{1} {N}_{2} + {m}_{2} {N}_{1}} {m}_{0} \\ \frac{1}{{L}^{2}} = 2 \frac{\vert γ \vert}{{ℏ}^{2}} \sqrt{{N}_{1} {N}_{2}} {m}_{0} \qquad ( 10 )$$

This equation (11) is referred to as a sine-Gordon equation, and as known can be used to give ground state solutions of phase difference ψ=0 or π, and a soliton solution as a minimum value solution. When there is no spatial fluctuation in the magnitude of the interaction (represented by parameter γ), the ground state solution to the phase difference is 0 when γ<0, and π when γ>0. The sign of the substance property γ determines whether the ground state solution becomes 0 or π. Energy corresponding to other soliton solutions present as minimum value solutions is slightly higher than the ground state energy.

Also, the phase difference rotates from 0 when γ<0 to 2π, and from −π when γ>0 to π. Esoliton, the energy of one soliton, is obtained from the following equation (11), and the soliton total phase difference slip Θsoliton is obtained from equation (12).

$$\begin{matrix}Esolitor = 8 \sqrt{2} {ℏ}^{4} \sqrt{{N}_{1} {N}_{2}} \sqrt{\frac{\vert γ \vert}{{m}_{0}}} & ( 11 ) \\ Θ soliton = \frac{\pm 2 π}{1 + \frac{{m}_{2} {N}_{1}}{{m}_{1} {N}_{2}}} & ( 12 )\end{matrix}$$

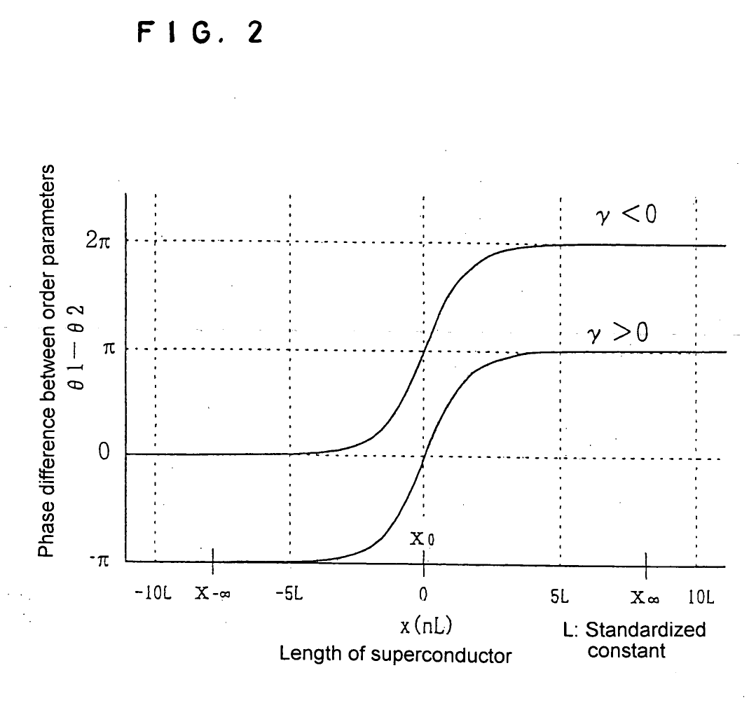

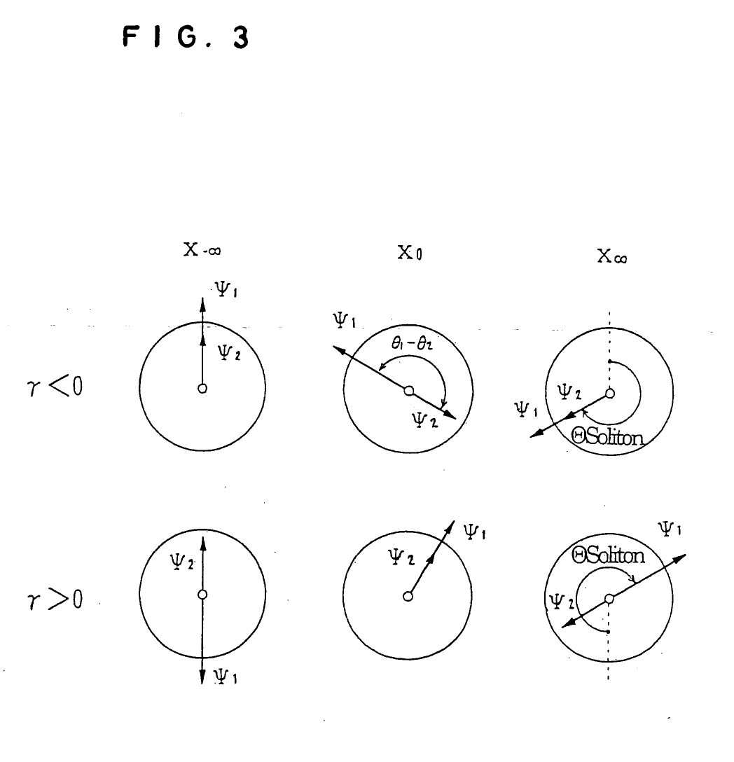

With respect to the one-dimensional case of FIGS. 2 and 3, the phase difference ψ that is the soliton is depicted schematically. The horizontal axis of FIG. 2 represents the length of the superconductor using a standardized constant L (defined by equation (10)) as the unit, and the vertical axis stands for phase difference ψ. The phase difference in the vicinity of x₀ represents the soliton. Phase slip occurs over the length of the superconductor, behind and in front of the soliton (the Θsoliton in FIG. 3). The soliton advances in the superconductor and is reflected at the superconductor ends x₋₄ and x₄. In the example of FIG. 3, order parameters are shown as vectors in a complex plane.

The phase difference constituting this soliton is maintained, so information can be stored in the form of phase differences. Moreover, −Θsoliton phase slip is also present when the same energy is carried in the reverse direction, so the soliton itself can have a + or − sign. The soliton enables storage of energy not accompanied by magnetic flux. Energy can also be stored in soliton units.

If x₋₄ and x₄ are connected to make the superconductor into a ring, for a boundary condition, the soliton phase slip Θsoliton will be compensated by means of the supercurrent. Therefore, supercurrent Je can be expressed by the following equations (13) to (15). With respect to the circulating supercurrent Je, Je soliton=0, so only the vector current Je_{A} component flows.

$$\begin{matrix}Je = {Je}_{A} + Je soliton & ( 13 ) \\ {Je}_{A} = - {e}^{2} A ( \frac{{N}_{1}}{{m}_{1}} + \frac{{N}_{2}}{{m}_{2}} ) & ( 14 ) \\ Je soliton = {\sum }_{v = 1 , 2} \frac{e ℏ {N}_{2}}{{m}_{v}} {∇}_{x} {θ}_{v} & ( 15 )\end{matrix}$$

The boundary condition of the order parameter in the superconductor ring is a phase difference of 2nπ per circuit (where n is an integer), so with the superconductor ring, the following equation (16) obtains. Equation (17) shows the phase difference relative to the point of connection of the two ends x₋₄ and x₄. Thus, the magnetic flux Φ induced in the superconductor ring will be as shown in equation (18). Here, Φ₀ is fluxoid quantum.

$$\begin{matrix}\int {∇}_{x} {θ}_{v} ⅆ x - \int \frac{e}{\overline{h}} A ⅆ x = 2 n π & ( 16 ) \\ \begin{matrix}\int {∇}_{x} {θ}_{v} ⅆ x = {\int }_{x - ∞}^{x ∞} \frac{\partial θ}{\partial x} ⅆ x \\ = θ ( {x}_{∞} ) - θ ( {x}_{- ∞} ) Θ solition\end{matrix} & ( 17 ) \\ Φ = \int A ⅆ x = ( \frac{- Φ soliton}{2 π} + n ) {Φ}_{0} & ( 18 )\end{matrix}$$

The present invention provides a recording method that records information in soliton units, a computing method that performs a computation, an information transmission method, an energy storage method and a magnetic flux measurement method that utilize the properties of phase difference solitons arising between superconducting order parameters present in multiple bands in a superconductor having multiple bands, and a quantum bit constitution method.

Instead of a Josephson device based on spatial arrangement, there may be used Josephson coupling between multiple superconducting order parameters superposed in the same space. Since in accordance with this method the strength of the Josephson coupling would be determined by the bulk properties rather than by the boundary properties, dependency on device processes is almost entirely eliminated. In addition, it would also enable Josephson junctions between three or more order parameters, which have not been possible with the conventional technology.

The use of solitons makes it possible to store energy without generating a magnetic field. Such a configuration enables the realization of phase difference solitons between plural order parameters.

Next, the information recording method, computing method, information transmission method, energy storage method, magnetic flux measurement method and quantum bit constitution method of the present invention will be individually described with reference to the drawings.

Information Recording Method:

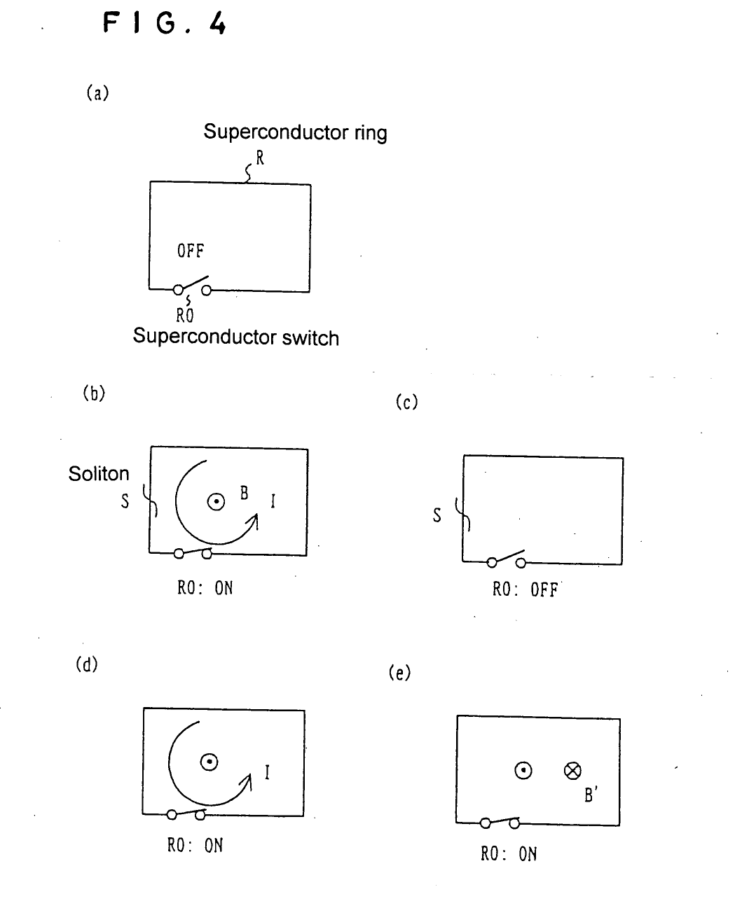

FIG. 4 shows a schematic depiction of an example of a method of recording solitons in a superconductor ring (hereinbelow “ring”) in accordance with the present invention. There is used, as the superconductor, CuₓBa₂Ca₃CuO_{y}, which is an example of a superconductor having multiple bands. By switching on a superconductor switch (hereinbelow “switch”) RO, the ring R is formed (FIG. 4(a)). A soliton S is created when a magnetic field B is applied within the ring, causing passage of a magnetic flux in the ring (FIG. 4(b)). The soliton S is still present even when the applied magnetic field is removed and the switch RO is switched off (FIG. 4(c)). When the switch RO is switched on, a magnetic flux Φ is generated in accordance with the boundary condition. If a reverse-direction magnetic field B′ is applied within the ring, the magnetic flux is cancelled and there is no constant circulation of electric current (FIG. 4(d)).

FIG. 4(c) corresponds to a storage state, and FIG. 4(d) corresponds to a storage erase state. Storage can still be erased even if the temperature of the superconductor is made high. When a magnetic field is applied in the reverse direction, a reverse-direction soliton S′ is created. Digital information can be stored by having soliton S correspond to “1” and soliton S′ to “0”.

Computing Method:

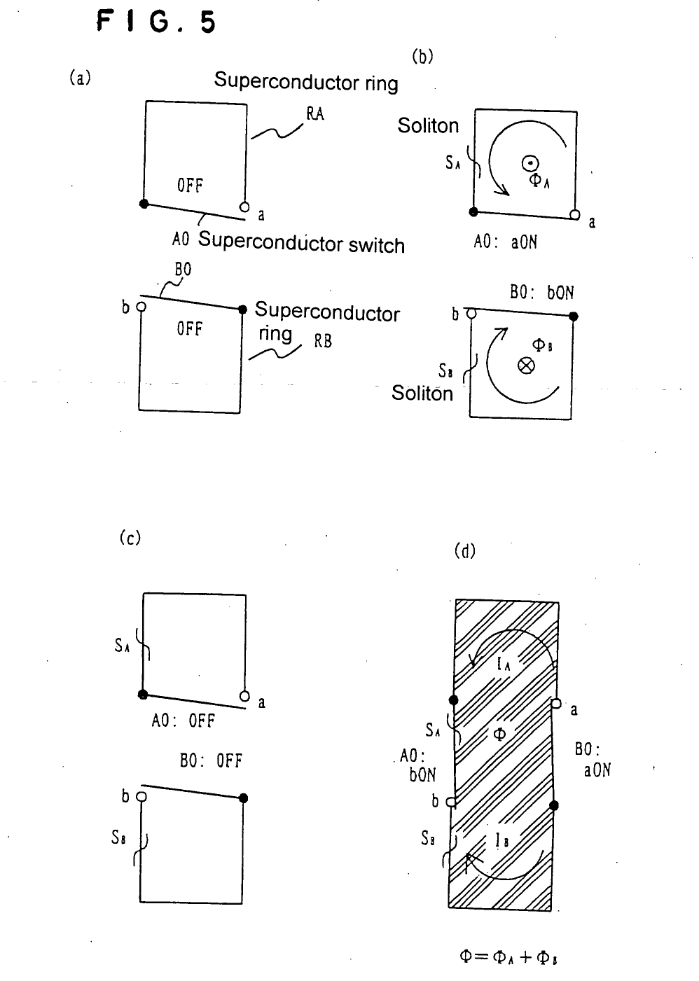

FIG. 5 is a schematic depiction of an example of the computing method according to the present invention. This is a superconductor circuit, with two rings R_{A} and R_{B} being connected to form one ring by means of two switches AO and BO. When configured as two rings R_{A} and R_{B}, switch AO is connected to terminal a and switch BO is connected to terminal b (FIG. 5(a)), and magnetic flux ΦA passes through ring R_{A} and magnetic flux ΦB passes through ring R_{B}, whereby solitons S_{A} and S_{B} are created in the respective rings R_{A} and R_{B} (FIG. 5(b)). The magnetic fluxes ΦA and ΦB are each of an amount that produces one soliton. Magnetic fluxes Φ_{A} and Φ_{B} are repeatedly applied to the rings to create solitons corresponding to a computation. The solitons continue to be present even when the switches AO and BO are both off (FIG. 5(c)). When switch AO is connected to terminal b and switch BO is connected to terminal a to form a single ring, supercurrents I_{A} and I_{B} flow according to the boundary condition, and magnetic flux Φ is generated by the combined current. The sum (or the difference in the case of an opposite applied flux, as in FIG. 5(b)) of the solitons can be computed by measuring this magnetic flux.

When there are several solitons and anti-solitons, since the flux trapped in the ring can be found by subtracting the total phase slip effect produced by the solitons and anti-solitons from an integer multiple of h/2e, the ring can be used to perform the operation of adding solitons and anti-solitons.

Information Transmission Method:

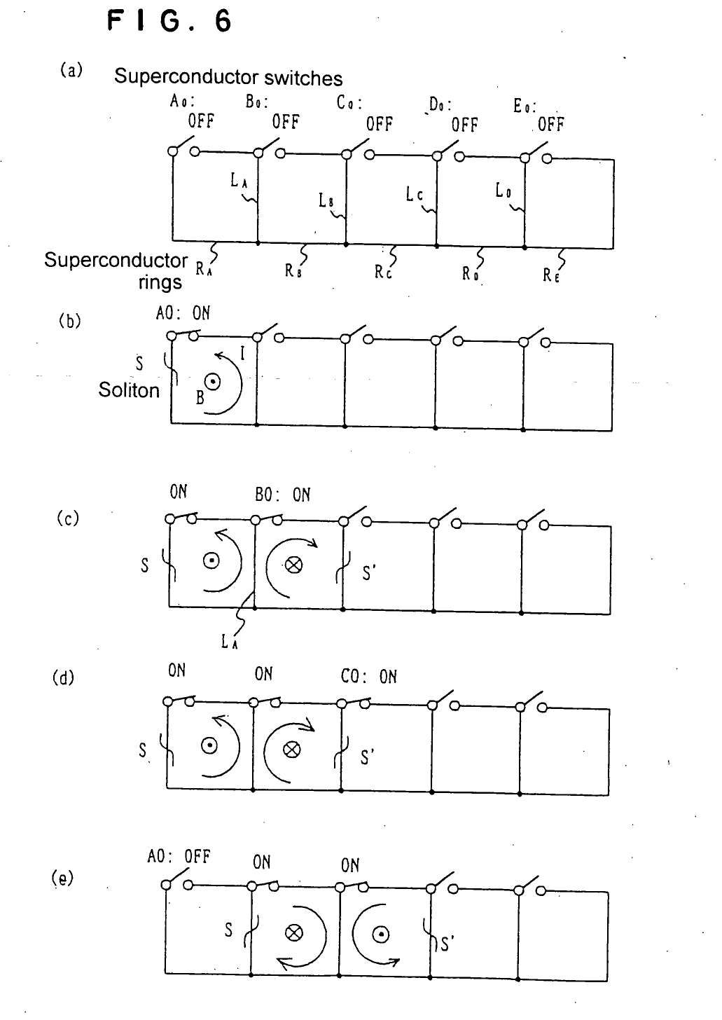

FIG. 6 shows an example of the information transmission method according to the present invention. FIG. 6(a) is a superconductor circuit constituted by connecting rings R_{A} to R_{E}. AO to EO are switches. When switch AO is switched on, a magnetic field B is applied to ring R_{A}, producing a magnetic flux. As a result, soliton S is created in ring A (FIG. 6(b)). After the soliton is created, switch BO is switched on, cutting off the magnetic field. If the band parameters are adjusted so that the energy when anti-solitons S= are created is lower than that when they are not created, the magnetic flux will wind around the superconductor L_{A} and soliton S will be created on the outside of the rings R_{A} and R_{B} (FIG. 6(c)).

Next, switch CO is switched on (FIG. 6(d)). When switch AO is switched off (FIG. 6(e)), since moving to the outside of the next rings R_{B} and R_{C} provides an energy advantage, the soliton moves to rings R_{B} and R_{C}. Information (S, S′) corresponding to the applied magnetic flux is transmitted. Information (S′, S) is transmitted if the magnetic field applied is the reverse of that shown in the drawing. It is possible to transmit digital information by having these information pairs correspond to ones and zeroes.

Energy Storage Method:

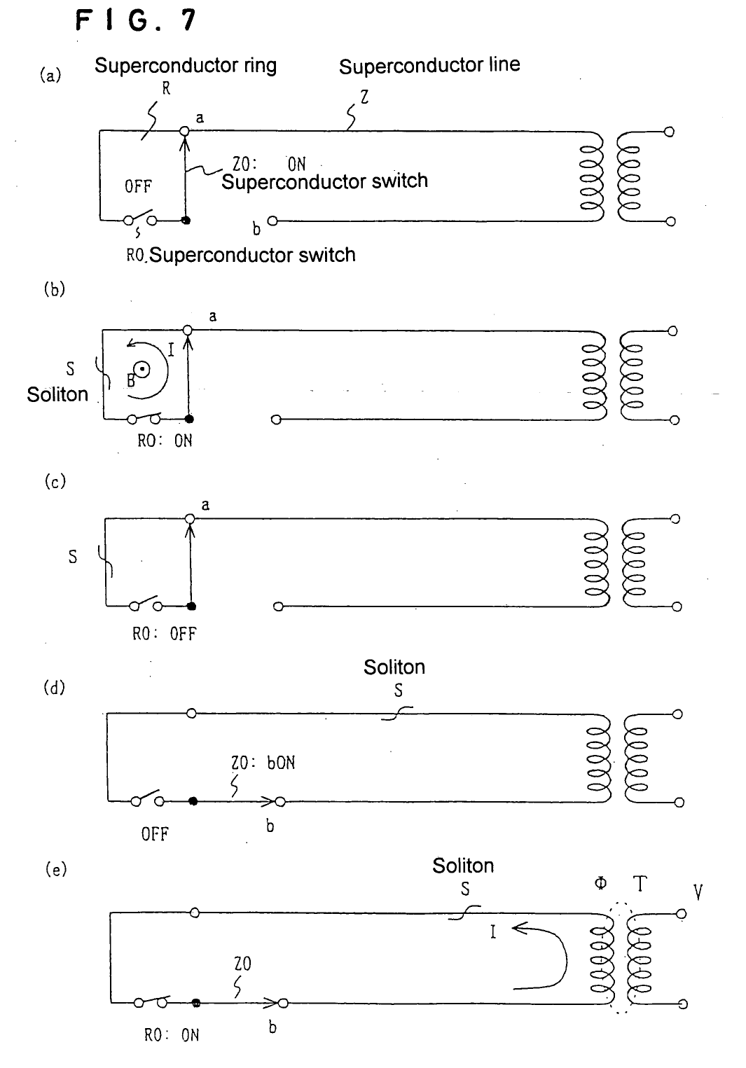

FIG. 7 shows an example of the energy storage method of the present invention.

Switch ZO is connected to terminal a and switch RO is switched on, forming ring R, and magnetic field B is applied in the ring, creating soliton S in ring R (FIG. 7(b)). If the applied magnetic field is removed after switching switch RO off, solitons S advance to superconductor line Z, and are stored there (FIG. 7(c)). When switch ZO is connected to terminal b, the presence of solitons in the superconductor line is ensured (FIG. 7(d)). When switch RO is switched on, in accordance with the boundary condition, a persistent current flows, and energy stored in the superconductor line is output via a superconductor transformer T (FIG. 7(e)). The amount of stored energy is determined by the number of times the magnetic field is applied.

Magnetic Flux Measurement Method:

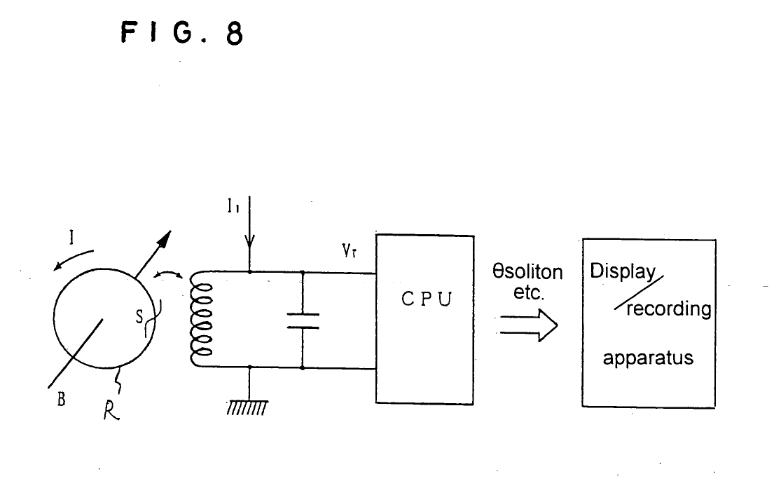

FIG. 8 shows an example of a measuring apparatus that implements an example of the magnetic flux measurement method of the present invention. When there is no soliton, from the boundary condition, the magnetic flux trapped in the superconductor ring will be an integer multiple of Φ=h/2e. However, as shown in FIG. 8, when one soliton enters, the boundary condition changes, and there has to be a flow of supercurrent to cancel the amount of phase difference due to the trapped soliton. From equation (15), the magnetic flux generated inside the superconductor ring by this supercurrent is an integer multiple of Φ₀=h/2e minus soliton-induced phase slip (1/(2π) ×h/2e). Thus, it is possible to measure magnetic flux that is smaller than the fluxoid quantum unit defined by Φ₀=h/2e.

Magnetic flux trapped in the ring R of FIG. 8 creates solitons in the ring. If n1 solitons are created, equation (18) becomes equation (19), with the output voltage V_{T} of the tank circuit being proportional to Φ of equation (19). The principle of this detection circuit is the same as that of RfSQUID.

$$Φ = - {n}^{′} \frac{Θ soliton}{2 π} {Φ}_{0} + n {Φ}_{0} \qquad ( 19 )$$

The CPU of FIG. 8 discriminates the difference between the periods of signals produced by Φsoliton and Φ₀ to calculate Φsoliton. The magnetic flux in Φsoliton units is determined using superconductor material constants, such as m₁, m₂, N₁ and N₂ (see equation (12)) and, as compared to magnetic flux in Φ₀ units, the resolution in the case of Φsoliton units is around ½ higher than that in the case of Φ₀ units in accordance with soliton-unit flux measurements, for example. With respect to detected Φsolitons, measured values of external magnetic flux are displayed and recorded by means of a display/recording apparatus.

Quantum Bit Constitution Method:

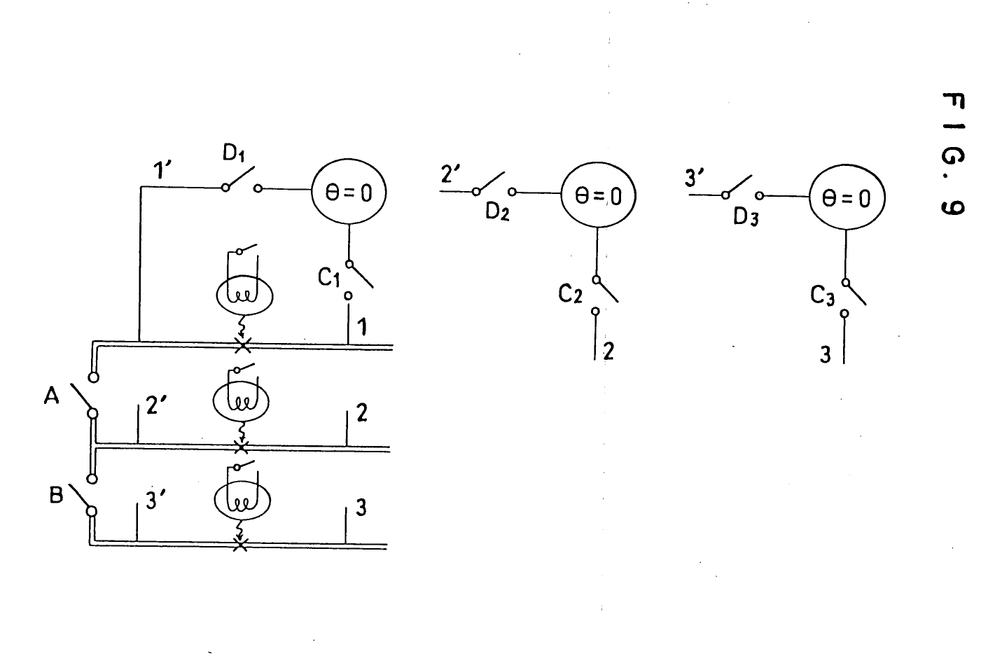

FIG. 9 shows an example of the quantum bit constitution method of the present invention. FIG. 9 shows an example of a three-quantum bit configuration, with a double-line indicating a multi-band superconductor electric line, and a single-line indicating an ordinary superconductor or multi-band superconductor electric line. Numerals 1, 2, 3, 1′, 2′ and 3′ denote how the electric lines are connected. First, switches C₁ to C₃ and switches D₁ to D₃ are switched on to align the phases of the reference superconductors θ=0 and the three multi-band superconductors indicated by a double-line, eliminating solitons. If necessary, solitons can be eliminated by an external field, such as in the method shown in FIG. 4.

Next, all of the switches A and B, C₁ to C₃ and D₁ to D₃ are switched off.

Then, a light source is used to irradiate the superconductors with light quanta having just the same energy as each soliton-creation energy, creating solitons and anti-solitons with a 50:50% probability. The created solitons and anti-solitons are each trapped by the three multi-band superconductors, producing a state in which soliton and anti-soliton are superimposed in the superconductors. This state of soliton and anti-soliton superimposition corresponds to 1 QuBit (1 quantum bit).

Computing between quantum bits, using a desired combination of on and off states of switches A and B, can be realized by performing this a desired number of times at a desired time interval and a desired time period.

After the computation, switches C₁ to C₃ and D₁ to D₃ are switched on, and the magnitude of the supercurrent flowing between the reference superconductors and between the multi-band superconductors is measured, and the QuBit state is observed.

### INDUSTRIAL APPLICABILITY

As described in the foregoing, it is possible to record, transmit and compute information by utilizing phase differences between multiple order parameters, which is useful as a control principle for superconducting electronics in which boundaries of Josephson devices based on spatial arrangement are eliminated. As an energy application, it is also useful as a technology for the storage of energy not accompanied by the generation of magnetic flux, which is ready even when the irreversible magnetic field is low. Also, since the integration technology is as simple as, or simpler than, existing superconductor device fabrication technology, phase differences between multiple order parameters can be utilized to provide readily integratable quantum bits.

1. An information recording method utilizing a superconductor having multiple bands, comprising the step of recording information, utilizing phase differences between superconducting order parameters present in the multiple bands in the superconductor.

2. A computing method utilizing a superconductor having multiple bands, comprising the step of performing a computation, utilizing phase difference solitons between superconducting order parameters present in the multiple bands in the superconductor.

3. An information transmission method utilizing a superconductor having multiple bands, comprising the step of transmitting information in units of phase difference solitons between superconducting order parameters present in the multiple bands in the superconductor.

4. An energy storage method utilizing a superconductor having multiple bands, that is based on phase difference solitons between superconducting order parameters present in the multiple bands in the superconductor.

5. A magnetic flux measurement method utilizing a superconductor having multiple bands, comprising the step of measuring magnetic fluxoid quantum in unit phase difference solitons between superconducting order parameters present in the multiple bands in the superconductor.

6. A quantum bit constitution method utilizing a superconductor having multiple bands to constitute quantum bits, comprising the step of utilizing phase differences between superconducting order parameters present in the multiple bands in the superconductor.
